(19) United States
(12) Patent Application Publication
(10) Pub. No.: US 2025/0305777 A1
(43) Pub. Date: Oct. 2, 2025

(54) HEAT SINK ASSEMBLY AND MANUFACTURING METHOD THEREOF

(71) Applicant: Molex, LLC, Lisle, IL (US)

(72) Inventors: Wen-Chih Chen, New Taipei City (TW); Che-Yuan Yang, New Taipei City (TW)

(21) Appl. No.: 19/090,443

(22) Filed: Mar. 26, 2025

(30) Foreign Application Priority Data
Mar. 28, 2024 (CN) 202410365502.8

(51) Int. Cl. F28F 3/12; F28F 3/02; F28F 21/06

(52) U.S. Cl. CPC F28F 3/12; F28F 3/022; F28F 21/067; F28F 2230/00; F28F 2255/143; F28F 2255/146

(57) ABSTRACT

A heat sink assembly and a manufacturing method thereof are provided. The heat sink assembly includes a heat dissipating base and a sealing member. The heat dissipating base includes a main body and a dissipating seat. The main body is mounted to a connector assembly, and an inner surface of the main body defines a passageway space. The heat dissipating seat is placed in the passageway space. The sealing member is provided in the passageway space. The sealing member has a fixing portion which is connected to the inner surface of the main body, and a floating portion which is connected to the fixing portion and the heat dissipating seat and is separated from the inner surface of the main body. Therefore, it can allow the heat dissipating seat to cooperate with contacting and abutting of a pluggable assembly to move relative to the main body, avoid the heat dissipating seat generating interference with the pluggable assembly, in turn attain an effect of promoting mounting firmness.

### TECHNICAL FIELD

The present disclosure relates to a heat sink assembly and a manufacturing method thereof, and particularly relates to a water-cooling type heat sink assembly which is adapted to perform heat exchange with a pluggable assembly and a manufacturing method thereof.

### BACKGROUND

A connector assembly will generate heat during operation, so it is common to open a window on a top of the connector assembly and mount a heat sink assembly to the window of the connector assembly, when a pluggable assembly inserts into the connector assembly, the pluggable assembly will upwardly contact and abut against the heat sink assembly at the window, so as to transfer heat generated in transmission between the connector assembly and the pluggable assembly to the heat sink assembly, thereby attaining an effect of lowering a temperature of the connector assembly and a temperature of the pluggable assembly. However, when the pluggable assembly upwardly contacts and abuts against the heat sink assembly, the heat sink assembly is often squeezed outwardly at the window, which results in that contact between the heat sink assembly and the pluggable assembly is poor, or the heat sink assembly is detached from the connector assembly.

### SUMMARY

Therefore, an object of the present disclosure is to provide a heat sink assembly which can solve the aforementioned problem.

Accordingly, a heat sink assembly of the present disclosure comprises a heat dissipating base and a sealing member. The heat dissipating base comprises a main body and at least one heat dissipating seat. An inner surface of the main body defines a passageway space which is adapted to allow a cooling liquid to flow therethrough. The heat dissipating seat is placed in the passageway space. The sealing member is provided in the passageway space. The sealing member has a fixing portion which is connected to the inner surface of the main body, and a floating portion which is connected to the fixing portion and the heat dissipating seat. The floating portion is separated from the inner surface of the main body and is capable of moving together with the heat dissipating seat relative to the main body.

In some embodiments, the heat sink assembly further comprises an adhesion promoting layer. A material of the main body is metal. The adhesion promoting layer is provided to the inner surface of the main body and is away from the heat dissipating seat. The fixing portion is connected to the inner surface of the main body via the adhesion promoting layer.

In some embodiments, the heat sink assembly further comprises another adhesion promoting layer. A material of the heat dissipating seat is metal. The another adhesion promoting layer is provided to a part of a surface of the heat dissipating seat. The floating portion is connected to the heat dissipating seat via the another adhesion promoting layer.

In some embodiments, a material of the sealing member is Liquid Silicone Rubber which is capable of being cured for formation.

In some embodiments, the main body further has at least one communication opening which is formed to an outer surface of the main body and is communicated to the passageway space. The heat dissipating seat has an abutting portion which protrudes from the communication opening. When an inward force is applied to the abutting portion, the floating portion will be brought by the heat dissipating seat to move and be deformed and move toward a direction away from the inner surface of the main body, so as to make the abutting portion withdraw toward an interior of the passageway space.

In some embodiments, the heat sink assembly further comprises an outer cover and at least one elastic member. The passageway space has a mount opening which is opposite to the communication opening. The outer cover covers a side of the main body away from the communication opening to close the mount opening. Two opposite ends of the elastic member respectively abut against the outer cover and the heat dissipating seat. When the abutting portion withdraws toward the interior of the passageway space, the elastic member will be brought by the heat dissipating seat to move and be compressed and generate an elastic restoring force. When the inward force applied to the abutting portion is released, the elastic member will be brought by the elastic restoring force to move and restore a length thereof and push the abutting portion out of the passageway space via the communication opening.

In some embodiments, the elastic member is a spring; the heat dissipating seat further has an erecting post which extends from the abutting portion toward the outer cover. The erecting post allows the elastic member to sheathe with elastic compressibility.

In some embodiments, the heat dissipating seat further has an annular encircling wall which encircles the erecting post. The elastic member is provided between the annular encircling wall and the erecting post, and sheathes the erecting post with elastic compressibility.

In some embodiments, the main body extends along a length direction. The communication opening and the mount opening are respectively formed to two sides of the main body which are spaced apart from each other in a thickness direction. The thickness direction is not parallel to the length direction. The heat dissipating base further comprises two joints, the two joints are respectively provided to two sides of the main body which are side by side in the length direction. One of the two joints is used to guide a cooling liquid into the passageway space, the other of the two joints is used to guide the cooling liquid out of the passageway space.

In some embodiments, the outer surface of the main body at the two sides of the main body which are side by side in the length direction respectively form two joining holes which are communicated to the passageway space. Each joint has a joining end. The two joining ends respectively insert into the two joining holes. The heat dissipating base further comprises two sealing rings which respectively sheathe two joining ends. Each sealing ring is used to seal a gap between the corresponding joining end and a hole wall of the joining hole.

In some embodiments, the main body has a bottom wall which extends along a length direction and a width direction, and an upright wall which extends from the bottom wall along a thickness direction. An inner surface of the bottom wall and an inner surface of the upright wall define the passageway space. The inner surface and an outer surface of the bottom wall are penetrated to form the communication opening. The length direction, the width direction and the thickness direction are not parallel each other. The heat dissipating seat further has an annular edge portion which movably abuts against the inner surface of the bottom wall. A side of the annular edge portion away from the bottom wall allows the floating portion to be connected therewith.

In some embodiments, the upright wall has a first surface portion which is connected to the inner surface of the bottom wall and a second surface portion which is connected to the first surface portion. The second surface portion allows the fixing portion to be connected therewith. The second surface portion is away from the communication opening relative to the first surface portion. The first surface portion and the inner surface of the bottom wall are separated from the floating portion.

In some embodiments, the sealing member has a top transverse segment, a longitudinal segment and a bottom transverse segment, the longitudinal segment connects the top transverse segment and the bottom transverse segment, the floating portion comprises a lower segment of the longitudinal segment and the bottom transverse segment, the bottom transverse segment extends toward a direction away from the longitudinal segment to connect the annular edge portion of the heat dissipating seat.

In some embodiments, the annular edge portion of the heat dissipating seat has a transverse portion which extends transversely from a periphery of the abutting portion toward a direction away from the abutting portion and a protruding edge portion which is formed to protrude upwardly from a top surface of the transverse portion, the protruding edge portion of the heat dissipating seat is positioned between the abutting portion and the longitudinal segment of the sealing member to make the protruding edge portion offset from the longitudinal segment by a distance.

In some embodiments, the heat sink assembly is adapted to be provided to a connector assembly, the connector assembly allows a pluggable assembly to insert therein, the heat dissipating seat allows the pluggable assembly to contact and abut thereagainst.

Another object of the present disclosure is to provide a manufacturing method of the aforementioned heat sink assembly.

A manufacturing method of a heat sink assembly of the present disclosure is adapted to be performed by a mold and a heat dissipating base. The heat dissipating base comprises a main body and at least one heat dissipating seat. The manufacturing method of the heat sink assembly comprises: placing the heat dissipating base into the mold; providing an adhesion promoting layer on an inner surface of the main body away from the heat dissipating seat; injecting a molding material into the mold to make the molding material engaged with the main body via the adhesion promoting layer, form a sealing member which connects the main body and the heat dissipating seat, and make a part of the main body which is not provided with the adhesion promoting layer separated from the sealing member; and taking the heat dissipating base together with the sealing member out of the mold to complete manufacturing of the heat sink assembly.

In some embodiments, the inner surface of the main body defines a passageway space which is adapted to allow a cooling liquid to flow therethrough, and the main body has at least one communication opening which is formed to an outer surface of the main body and is communicated to the passageway space. The passageway space has a mount opening which is opposite to the communication opening. The heat dissipating seat is placed in the passageway space and has an abutting portion which protrudes from the communication opening. The manufacturing method of the heat sink assembly further comprises: after taking the heat dissipating base together with the sealing member out the mold, next, mounting at least one elastic member to a side of the heat dissipating seat adjacent to the mount opening, next, making an outer cover cover a side of the main body away from the communication opening to close the mount opening and make two opposite ends of the elastic member respectively abut against the outer cover and the heat dissipating seat.

In some embodiments, in process of making the outer cover cover the side of the main body away from the communication opening to close the mount opening, the outer cover is engaged with the main body by a welding manner and covers the main body.

In some embodiments, the main body extends along a length direction. The communication opening and the mount opening are respectively formed to two sides of the main body which are spaced apart from each other in a thickness direction. The thickness direction is not parallel to the length direction. The manufacturing method of the heat sink assembly further comprises: before placing the heat dissipating base into the mold, firstly mounting two joints respectively to two sides of the main body which are side by side in the length direction, so as to make the two joints respectively communicated with two opposite ends of the passageway space.

In some embodiments, the outer surface of the main body at the two sides which are side by side in the length direction respectively form two joining holes which are communicated to the passageway space. Each joint has a joining end. The manufacturing method of the heat sink assembly further comprises: before mounting the two joints respectively to the two sides of the main body which are side by side in the length direction, firstly coating two sealing rings with an adhesive and then respectively making the two sealing rings sheathe the two joining ends, next, inserting the joining ends of the two joints together with the two sealing rings respectively into the two joining holes, so as to make each sealing ring adhere the corresponding joining end and a hole wall of the joining hole with sealing.

In some embodiments, a material of the main body is metal, the molding material is Liquid Silicone Rubber.

In some embodiments, a material of the heat dissipating seat is metal, the manufacturing method of the heat sink assembly further comprises: after placing the heat dissipating base into the mold, further providing another adhesion promoting layer on a part of a surface of the heat dissipating seat; after providing the two adhesion promoting layers respectively on the inner surface of the main body away from the heat dissipating seat and the part of the surface of the heat dissipating seat, injecting a molding material into the mold to make the molding material respectively engaged with the main body and the heat dissipating seat via the two adhesion promoting layers respectively, form the sealing member which connects the main body and the heat dissipating seat, and make the part of the main body which is not provided with the adhesion promoting layer separated from the sealing member.

The effect of the present disclosure lies in that: by the design that the floating portion is separated from the main body, it can allow the heat dissipating seat to cooperate with contacting and abutting of the pluggable assembly to move relative to the main body, avoid the heat dissipating seat generating interference with the pluggable assembly, in turn attain an effect of promoting mounting firmness. On the other hand, by that the inner surface of the main body is provided with the adhesion promoting layer, it can allow the sealing member to be connected with the main body via the adhesion promoting layer while the molding material is cured for formation, and a part of the main body which is not provided with the adhesion promoting layer is separated from the sealing member, so as to complete manufacturing of the heat sink assembly.

### BRIEF DESCRIPTION OF THE DRAWINGS

Other features and effects of the present disclosure will be apparent from an embodiment with reference to the drawings, in which:

FIG. 1 is a perspective view illustrating an embodiment of a heat sink assembly of the present disclosure;

FIG. 2 is a partially exploded view of the embodiment;

FIG. 3 is a partially exploded view of the embodiment from another angle;

FIG. 4 is a perspective exploded view illustrating implementing details of a heat dissipating base of the embodiment;

FIG. 5 is a partially enlarged view of FIG. 4;

FIG. 6 is a cross sectional view taken along a line VI-VI of FIG. 1;

FIG. 7 is an enlarged view of a part indicated by a circle in FIG. 6;

FIG. 8 is an enlarged view similar to FIG. 7 and illustrating a changed implementing manner of a heat dissipating seat and a sealing member of the embodiment in a different use state;

FIG. 9 is a flowchart diagram illustrating a manufacturing method of the embodiment;

FIG. 10 is a perspective view illustrating a connecting relationship among a main body, a plurality of heat dissipating seats, two joints and two sealing rings of the heat dissipating base;

FIG. 11 is a schematic view illustrating one of steps of the manufacturing method of the embodiment;

FIG. 12 is an enlarged view of a part indicated by a circle in FIG. 11;

FIG. 13 is a schematic view illustrating another step of the manufacturing method of the embodiment; and

FIG. 14 is a schematic view illustrating still another step of the manufacturing method of the embodiment.

### DETAILED DESCRIPTION

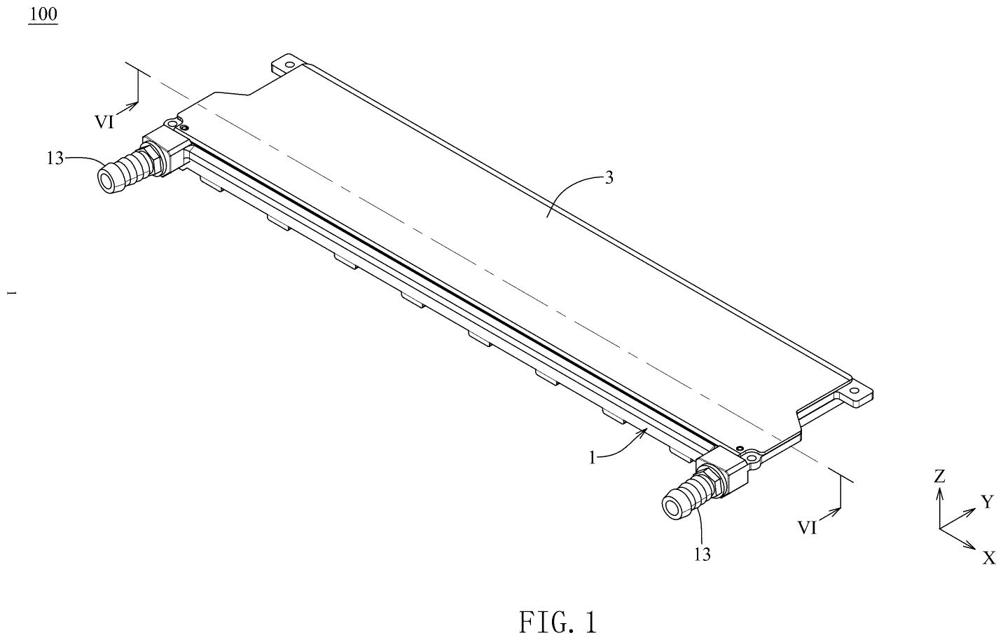

Referring to FIG. 1, an embodiment of a heat sink assembly 100 of the present disclosure is illustrated. Directional terms in the contents described herein are firstly defined. In later description, orientation expressing, such as “front”, “rear”, “left” and “right”, with respect to structure configuration of the heat sink assembly 100 is defined on a basis of up, down, left and right of use environment of the heat sink assembly 100 and page faces of the figures. In FIG. 1, a lower left side in the figure is defined as front, an upper right side in the figure is defined as rear, an upper left side in the figure is defined as left, and a lower right side in the figure is defined as right. And, a direction from left to right of the heat sink assembly 100 is defined as a length direction X, a direction from front to rear of the heat sink assembly 100 is defined as a width direction Y, and a direction from bottom to top of the heat sink assembly 100 is defined a thickness direction Z. Any every two of the length direction X, the width direction Y and the thickness direction Z are not parallel to each other.

Referring to FIG. 1 to FIG. 3, the heat sink assembly 100 is adapted to be provided to a plurality of connector assemblies not shown in the figures. Each connector assembly allows a pluggable assembly (not shown) to insert therein. Each connector assembly defines an inserting groove which is opened forwardly or rearwardly, and a top surface of each connector assembly is formed with a window which is communicated to the corresponding inserting groove. For example, each pluggable assembly is an optical fiber transmission plug of QSFP-DD (Quad Small Form-factor-Double Density) as packaging specification, but the present disclosure is not limited thereto. Each pluggable assembly removably inserts into the corresponding inserting groove, and a part of each pluggable assembly is exposed under the corresponding window. The heat sink assembly 100 is adapted to perform heat exchange with the plurality of pluggable assemblies when the plurality of pluggable assemblies insert into the plurality of connector assemblies respectively. The heat sink assembly 100 includes a heat dissipating base 1, a sealing member 2, an outer cover 3, a plurality of elastic members 4 and a plurality of adhesion promoting layers 5.

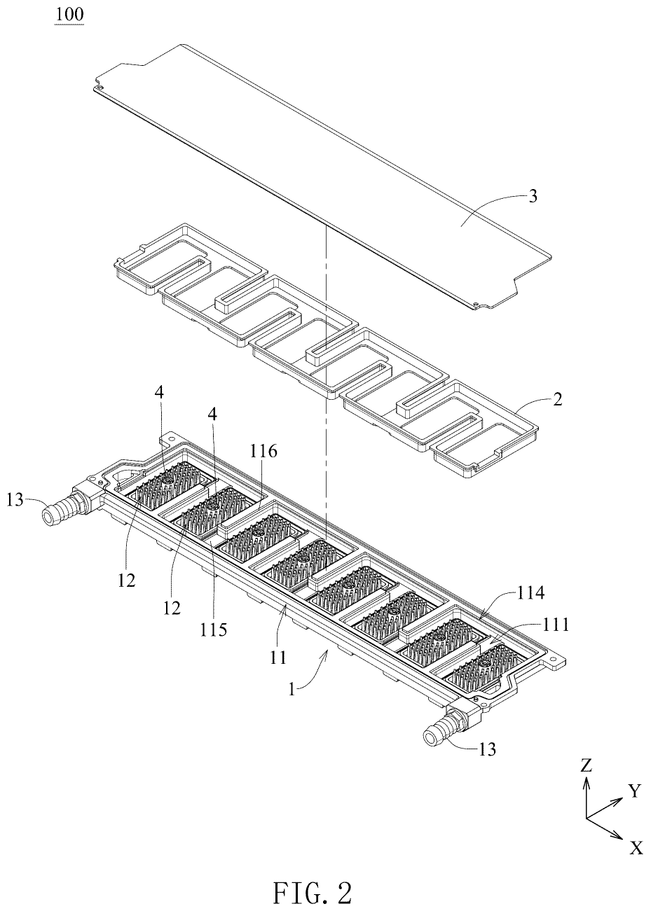

Referring to FIG. 2 to FIG. 4, the heat dissipating base 1 includes a main body 11, a plurality of heat dissipating seats 12, two joints 13 and two sealing rings 14. The main body 11 is adapted to be mounted to a side of the plurality of connector assemblies which are provided with the windows. The main body 11 is an elongated flat shape, and extends along the length direction X. An inner surface of the main body 11 defines a passageway space 111 which is adapted to allow a cooling liquid (not shown) to flow therethrough, and the main body 11 has a plurality of communication openings 112 which are formed to an outer surface of the main body 11 and are communicated to the passageway space 111, and two joining holes 113 which are formed to the outer surface of the main body 11 and are communicated to the passageway space 111. The passageway space 111 extends to meander front and rear along the length direction X, so as to lengthen a time that the cooling liquid flows through the passageway space 111 and make a contact area between the main body 11 and the cooling liquid increased, thereby promoting heat exchange efficiency between the heat dissipating base 1 and the cooling liquid. The plurality of communication openings 112 are arranged in the length direction X, and are respectively aligned with the windows of the plurality of connector assemblies. The two joining holes 113 are respectively formed to the outer surface at two sides of the main body 11 which are side by side in the length direction X (that is, the two joining holes 113 are respectively positioned to a left side and a right side of the main body 11), and the two joining holes 113 are spaced apart from the plurality of communication openings 112. In the present embodiment, a material of the main body 11 is metal, so the main body 11 is a rigid structure, which is beneficial to promote heat exchange efficiency and may bear up to a water pressure of 100 pounds per square inch (100 psi). The number of the plurality of communication openings 112 takes eight as example, so as to match with the windows of the plurality of connector assemblies, but the number of the communication opening 112 also may be only one or two to seven or nine or more, the present disclosure is not limited to a particular number.

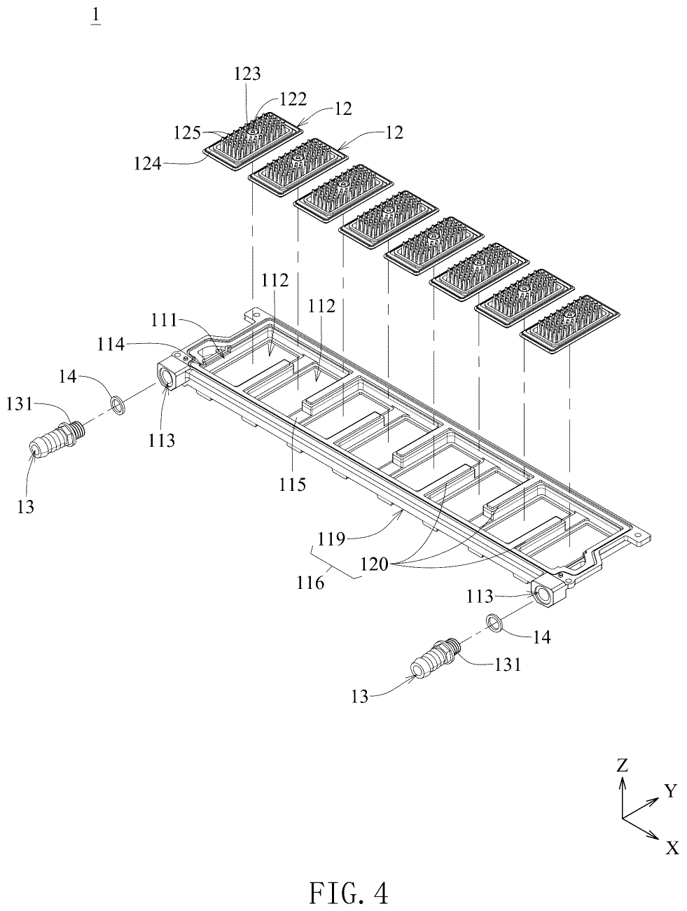

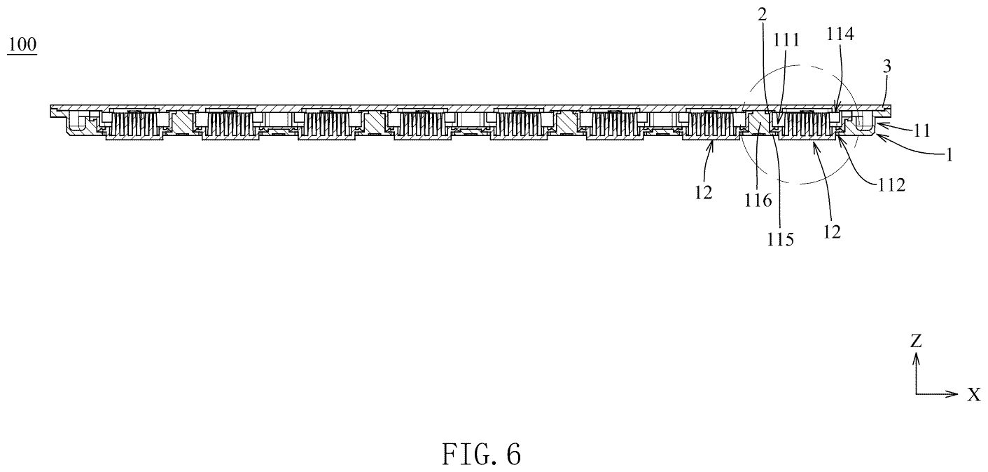

Referring to FIG. 4 to FIG. 7, specifically, the passageway space 111 has a mount opening 114 which is toward the up. The mount opening 114 is opposite to each communication opening 112. Each communication opening 112 and the mount opening 114 are respectively formed to two sides of the main body 11 which are spaced apart from each other in the thickness direction Z (that is, a top side and a bottom side of the main body 11). The main body 11 has a bottom wall 115 which extends along the length direction X and the width direction Y, and an upright wall 116 which extends from the bottom wall 115 along the thickness direction Z. An inner surface and an outer surface of the bottom wall 115 are penetrated at a plurality of locations of the bottom wall 115 to form the plurality of communication openings 112 which are arranged in the length direction X (that is, each communication opening 112 is toward the down). The upright wall 116 has a first surface portion 117 which is connected to the inner surface of the bottom wall 115, and a second surface portion 118 which is connected to the first surface portion 117. The second surface portion 118 is away from the communication opening 112 relative to the first surface portion 117.

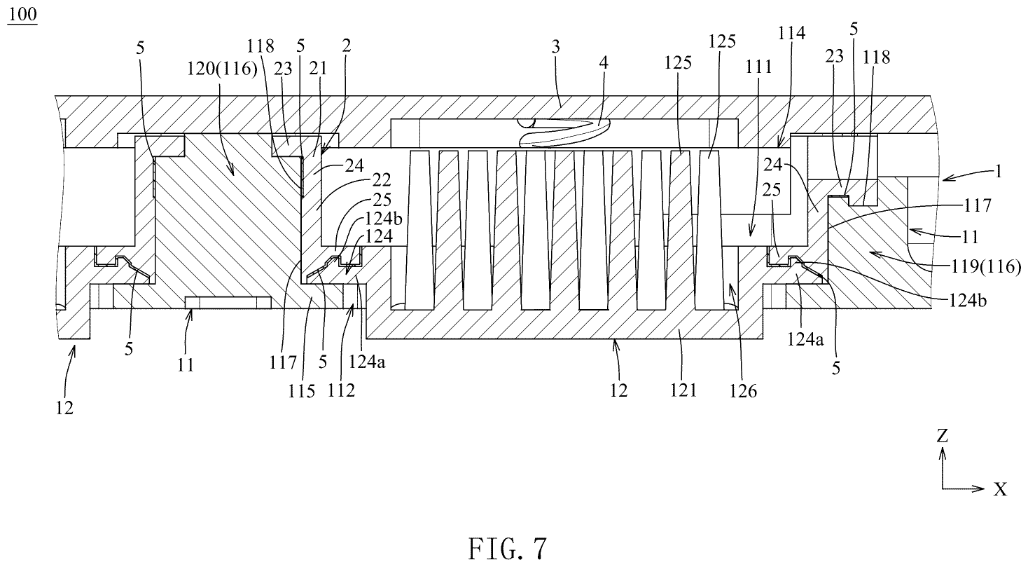

In the present embodiment, the upright wall 116 has an outer wall portion 119 which is connected to an outer periphery of the bottom wall 115 and encircles the plurality of communication openings 112 from the outside, and a plurality of inner wall portions 120 which are connected to an inner surface of the outer wall portion 119 and extend in the width direction Y. The plurality of inner wall portions 120 each are positioned between every two adjacent communication openings 112, and the adjacent two inner wall portions 120 are respectively connected to two opposite sides of the outer wall portion 119 in the width direction Y. The inner surface of the bottom wall 115 and an inner surface of the upright wall 116 (that is, the outer wall portion 119 and the plurality of inner wall portions 120) together define the passageway space 111 which extends to meander front and rear along the length direction X. An outer surface of the outer wall portion 119 forms the two joining holes 113. Moreover, a part of the inner surface of the outer wall portion 119 and a part of an inner surface of the inner wall portion 120 which are connected to the bottom wall 115 and define a bottom portion of the passageway space 111 are defined as the first surface portion 117, that is, the first surface portion 117 extends from the bottom wall 115 along the thickness direction Z (upwardly) to encircle each communication opening 112 from the outside. A part of the inner surface of the outer wall portion 119 and a part of the inner surface of the inner wall portion 120 which are connected to the first surface portion 117 and define the bottom portion of the passageway space 111 are defined as the second surface portion 118, that is, the second surface portion 118 extends from the first surface portion 117 toward a direction away from the plurality of communication openings 112 (upwardly) in the thickness direction Z, so the second surface portion 118 similarly encircles each communication opening 112 from the outside, but it is noted that, as shown in FIG. 7, the second surface portion 118 at a location of the outer wall portion 119 whose height is lower than the adjacent inner wall portion 120 (that is, at a location which defines the communication opening 112 of the passageway space 111) extends from the first surface portion 117 toward a direction away from the plurality of communication openings 112 in the length direction X (rightward in FIG. 7).

The plurality of heat dissipating seats 12 may be movably up and down placed in the passageway space 111, and respectively allow the plurality of pluggable assemblies to contact and abut thereagainst. Specifically, each heat dissipating seat 12 has an abutting portion 121, an erecting post 122, an annular encircling wall 123, an annular edge portion 124 and a plurality of post-shaped fins 125. Each abutting portion 121 is in form of cuboid wall portion structure and a top surface of each abutting portion 121 is depressed downwardly to form a recessed groove 126 which is communicated with the passageway space 111. Bottom portions of the plurality of abutting portions 121 respectively protrude from the plurality of communication openings 112, and respectively insert into the windows of the plurality of connector assemblies to respectively allow the plurality of pluggable assemblies to contact and abut thereagainst. Each erecting post 122 is in form of cylinder shape and extends from a top face of the corresponding abutting portion 121 (that is, a groove bottom wall of the recessed groove 126) toward a direction close to the outer cover 3. Each annular encircling wall 123 extends from the groove bottom wall of the corresponding recessed groove 126 toward the direction close to the outer cover 3, encircles the corresponding erecting post 122 and is spaced apart from the corresponding erecting post 122. Each annular edge portion 124 is positioned in the passageway space 111, and extends from an outer periphery surface of the corresponding abutting portion 121 (that is, an outer surface of the abutting portion 121 at a front side, a rear side, a left side and a right side of the abutting portion 121) toward a direction away from the corresponding erecting post 122 in the length direction X and the width direction Y, that is, entirely extends transversely from a periphery of the abutting portion 121 toward a direction away from the abutting portion 121. Each annular edge portion 124 movably abuts against the inner surface of the bottom wall 115, and is limited by the bottom wall 115 so that each annular edge portion 124 cannot move downwardly and the corresponding heat dissipating seat 12 cannot leave the main body 11 from the corresponding communication opening 112, in the present embodiment, the annular edge portion 124 has a transverse portion 124a which extends transversely from the periphery of the abutting portion 121 toward the direction away from the abutting portion 121 and a protruding edge portion 124b which is formed to protrude upwardly from a top surface of the transverse portion 124a, a cross section of the protruding edge portion 124b may be substantially in form of convex block shape and annularly encircles the abutting portion 121. The plurality of post-shaped fins 125 extend from the groove bottom wall of the corresponding recessed groove 126 toward the direction close to the outer cover 3, and are distributed outside the annular encircling wall 123. By the design on the plurality of post-shaped fins 125 in shape, an entire surface area of the heat dissipating seat 12 can be increased. In the present embodiment, the number of the plurality of heat dissipating seats 12 is the same as the number of the plurality of communication openings 112, and takes eight as example, but the number of the plurality of heat dissipating seats 12 is not limited to a particular number and can be determined as practical need. Moreover, a material of the plurality of heat dissipating seats 12 is metal, which is beneficial to promoting heat exchange efficiency.

Referring to FIG. 2, FIG. 4, the two joints 13 are respectively provided to the two sides of the main body 11 which are side by side in the length direction X, that is, the two joints 13 are respectively mounted to the two joining holes 113 so as to be positioned to the left side and the right side of the main body 11. One of the two joints 13 is used to guide the cooling liquid into the passageway space 111, the other of the two joints 13 is used to guide the cooling liquid out of the passageway space 111. Specifically, each joint 13 has a joining end 131. The two joining ends 131 respectively insert into the two joining holes 113. And the two sealing rings 14 respectively sheathe two joining ends 131. Each sealing ring 14 is in form of circle ring, for example is an O-ring, but the present disclosure is not limited thereto. Each sealing ring 14 is used to seal a gap between the corresponding joining end 131 and a hole wall of the joining hole 113, so as to prevent the cooling liquid from leaking outwardly via the gap between the joining end 131 and the hole wall of the joining hole 113.

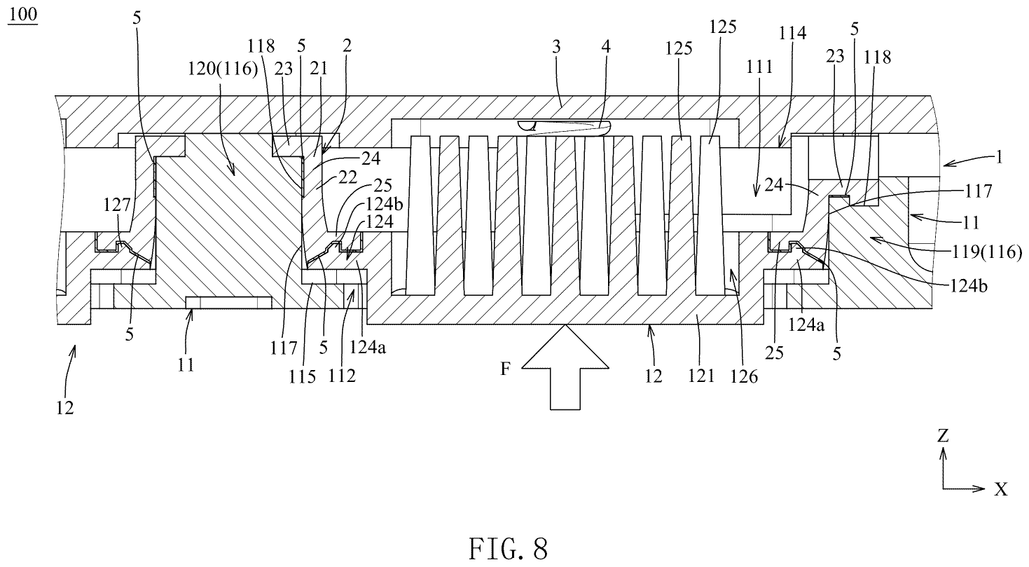

Referring to FIG. 7 and FIG. 8, the plurality of adhesion promoting layers 5 are respectively provided to the inner surface of the main body 11 away from the plurality of heat dissipating seats 12 and parts of surfaces of the plurality of heat dissipating seats 12. Specifically, one of the plurality of adhesion promoting layers 5 is provided to the second surface portion 118, moreover, taking the second surface portions 118 shown in FIG. 7 as example, the second surface portion 118 of the inner wall portion 120 on the left of the page surface of the figure includes a side surface which extends vertically, the second surface portion 118 of the outer wall portion 119 on the right of the page surface of the figure includes a top surface which extends horizontally, in other words, according to practical structure, one of the plurality of adhesion promoting layers 5 may be coated on various surfaces of the upright wall 116 as practical height needed. And the other of the plurality of adhesion promoting layers 5 are respectively provided to one sides of the annular edge portions 124 of the plurality of heat dissipating seats 12 away from the bottom wall 115, that is, top surfaces of the transverse portions 124a of the annular edge portions 124 and top surfaces of the protruding edge portions 124b of the annular edge portions 124 are also coated with the adhesion promoting layers 5 respectively. The plurality of adhesion promoting layers 5 are a surface treating agent (primer) in form of thin film, and is used for surface modification of the main body 11 and the plurality of heat dissipating seats 12, so as to make the main body 11 whose material is metal and the plurality of heat dissipating seats 12 whose material is metal are easily engaged with a soft material (for example Liquid Silicone Rubber (LSR)). Moreover, the number of the plurality of adhesion promoting layers 5 correspond to a sum of the number of the main body 11 and the number of the plurality of heat dissipating seats 12 and take nine as example (only three shown in FIG. 7). But in other implementing manners, the heat sink assembly 100 also may include only one adhesion promoting layer 5, and the adhesion promoting layer 5 is only provided to the second surface portion 118; or the number of the heat dissipating seat 12 is only one, the number of the plurality of adhesion promoting layers 5 correspond to a sum of the number of the main body 11 and one heat dissipating seat 12 and takes two as example, the number of the adhesion promoting layer 5 can be determined as practical need.

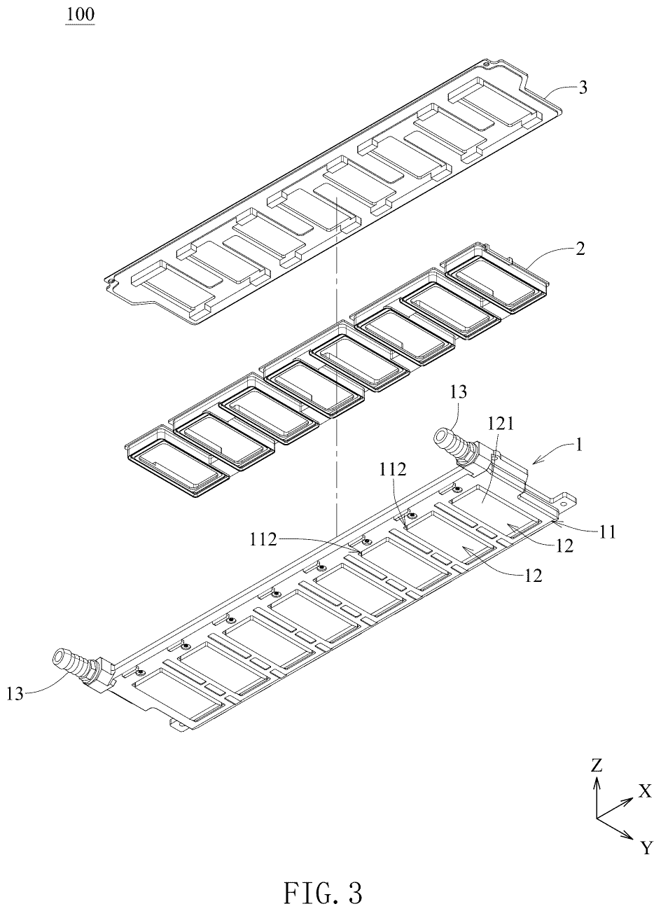

Referring to FIG. 2, FIG. 3, FIG. 7 and FIG. 8, the sealing member 2 is provided in the passageway space 111, and is used to seal engaged locations between the inner surface of the main body 11 and the plurality of heat dissipating seats 12. As shown in FIG. 7, the sealing member 2 has a fixing portion 21 (that is, a top portion of the sealing member 2) which is connected to the inner surface of the main body 11 and is spaced apart from the plurality of heat dissipating seats 12 in the thickness direction Z, and a floating portion 22 which is connected to the fixing portion 21 and the plurality of heat dissipating seats 12. A side of the floating portion 22 facing the main body 11 is separated from the main body 11 so that the floating portion 22 is capable of moving together with the plurality of heat dissipating seats 12 relative to the main body 11. Specifically, the fixing portion 21 is firmly connected to the inner surface of the main body 11 (that is, the second surface portion 118) via one of the plurality of adhesion promoting layers 5, so that the fixing portion 21 cannot move relative to the main body 11. A part of the floating portion 22 (that is, a bottom portion of the sealing member 2) is connected to a bottom portion of the fixing portion 21, another part of the floating portion 22 is connected to the one sides of the annular edge portions 124 of the plurality of heat dissipating seats 12 away from the bottom wall 115 via the other of the plurality of adhesion promoting layers 5. In other words, the floating portion 22 is separated from an inner surface of the first surface portion 117 and the inner surface of the bottom wall 115. By a coating range of the adhesion promoting layer 5, elasticity of displacement of the heat dissipating seat 12 when the heat dissipating seat 12 is subjected to a force may be adjusted.

Moreover, as shown in FIG. 7 and FIG. 8, in the present embodiment, a structure of the sealing member 2 which is positioned at each of the outer wall portion 119 and the plurality of inner wall portions 120 has a top transverse segment 23, a longitudinal segment 24 and a bottom transverse segment 25, taking the structure which is positioned at the inner wall portion 120 on the left side of the page surface of FIG. 7 as example, the longitudinal segment 24 is connected between the top transverse segment 23 and the bottom transverse segment 25, and a position of the longitudinal segment 24 is positioned to a side surface of the inner wall portion 120, the aforementioned fixing portion 21 may include an upper segment of the longitudinal segment 24 and the top transverse segment 23, the floating portion 22 may include a lower segment of the longitudinal segment 24 and the bottom transverse segment 25, and the bottom transverse segment 25 extends toward a direction away from the longitudinal segment 24 to connect the annular edge portion 124 of the heat dissipating seat 12. In the present embodiment, a material of the sealing member 2 is Liquid Silicone Rubber which may be cured for formation, but the present disclosure is not limited thereto, the material of the sealing member 2 also may be other soft material which is elastically deformable after cured. Moreover, when the heat sink assembly 100 only includes one adhesion promoting layer 5 which is provided to the second surface portion 118, the floating portion 22 also may be engaged with the plurality of heat dissipating seats 12 by other connecting manner (for example adhering).

The outer cover 3 covers a side of the main body 11 which is away from the plurality of communication openings 112, so as to close the mount opening 114. The outer cover 3 is a rigid structure, and thus may bear up to a water pressure of 100 pounds per square inch (100 psi).

Referring to FIG. 7 and FIG. 8, when any pluggable assembly inserts into the corresponding connector assembly, the pluggable assembly will apply an inward force F (schematically shown by an arrow in FIG. 8) to the adjacent abutting portion 121, so as to make the corresponding abutting portion 121 withdraw the corresponding window. When the corresponding abutting portion 121 is applied with the inward force F, the corresponding heat dissipating seat 12 will be pushed to move toward the direction close to the outer cover 3, at this time, because the floating portion 22 is separated from the main body 11, the floating portion 22 will be brought by the corresponding heat dissipating seat 12 to move and be deformed and move toward a direction away from the inner surface of the main body 11, so as to make the corresponding abutting portion 121 withdraw toward an interior of the passageway space 111, which allows the pluggable assembly to contact and abut against the corresponding abutting portion 121 and can generate the elasticity of displacement of the heat dissipating seat 12 when the heat dissipating seat 12 is subjected to a force.

Moreover, as shown in FIG. 8, in the present embodiment, the annular edge portion 124 is designed to include the transverse portion 124a and the protruding edge portion 124b, and the bottom transverse segment 25 of the sealing member 2 extends toward the direction away from the longitudinal segment 24 relative to the longitudinal segment 24 to be connected to the annular edge portion 124 of the heat dissipating seat 12, when the heat dissipating seat 12 is pushed to move toward the direction close to the outer cover 3, the annular edge portion 124 brings the bottom transverse segment 25 of the sealing member 2 to move upwardly, because the bottom transverse segment 25 extends toward the direction away from the longitudinal segment 24 and the protruding edge portion 124b of the heat dissipating seat 12 is positioned between abutting portion 121 and the longitudinal segment 24 of the sealing member 2, the protruding edge portion 124b will be offset from the longitudinal segment 24 by a distance, at this time, the bottom transverse segment 25 is subjected to a component force, which brings the floating portion 22 to move toward a direction leaving the side surface of the outer wall portion 119 and the side surface of the inner wall portion 120, is brought to move and generate deformation toward the direction leaving the side surface of the outer wall portion 119 and the side surface of the inner wall portion 120, which makes the floating portion 22 elastically deformed more easily.

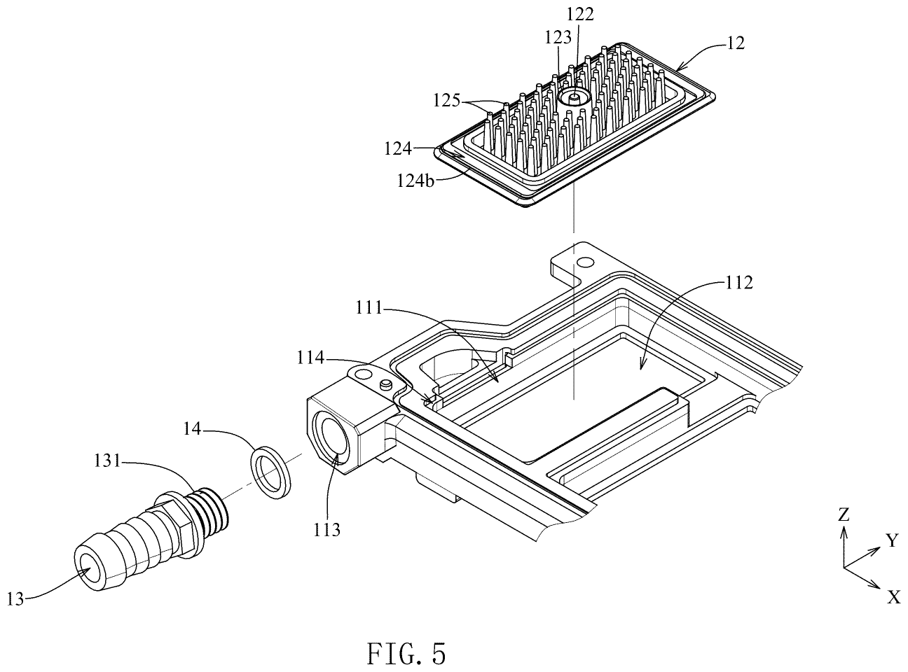

Referring to FIG. 2, FIG. 5 and FIG. 8, the plurality of elastic members 4 are respectively provided to the plurality of heat dissipating seats 12. Two opposite ends of each elastic member 4 respectively abut against the outer cover 3 and the corresponding heat dissipating seat 12. Each elastic member 4 is capable of being compressed or restoring a length thereof. When any abutting portion 121 withdraws toward the interior of the passageway space 111, the corresponding elastic member 4 will be brought by the corresponding heat dissipating seat 12 to move and be compressed and generate an elastic restoring force. When the inward force F applied to the corresponding abutting portion 121 is released, the corresponding elastic member 4 will be brought by the elastic restoring force to move and restore the length thereof, and push the corresponding abutting portion 121 out of the passageway space 111 via the corresponding communication opening 112, to make the corresponding abutting portion 121 automatically insert into the corresponding window, and make the corresponding abutting portion 121 restore to a state before the corresponding abutting portion 121 is subjected to a force. Preferably, each elastic member 4 is a spring, each elastic member 4 may respectively sheathe the erecting post 122 of the corresponding heat dissipating seat 12 with elastic compressibility, and be provided between the corresponding annular encircling wall 123 and the corresponding erecting post 122, therefore, when each elastic member 4 is compressed or restores the length thereof, each elastic member 4 is limited by the corresponding annular encircling wall 123 and thus does not interfere with the adjacent post-shaped fins 125.

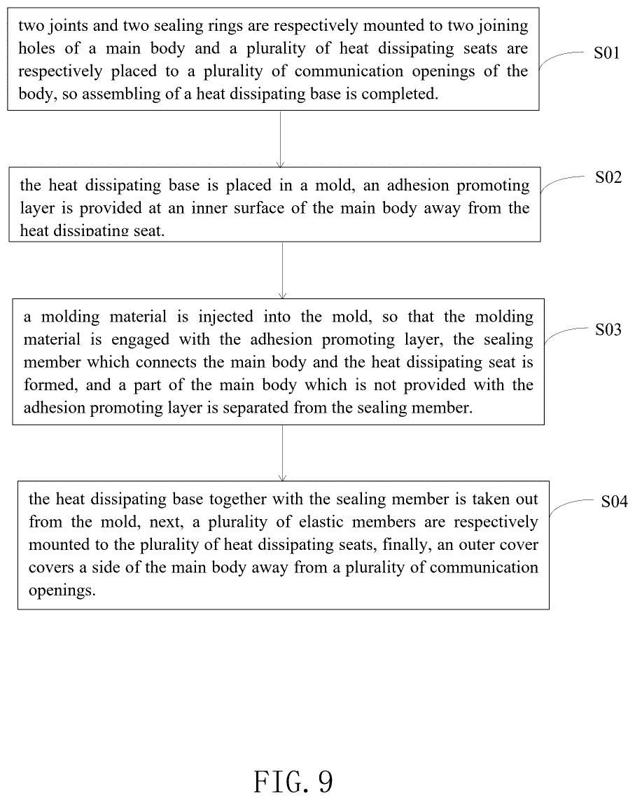

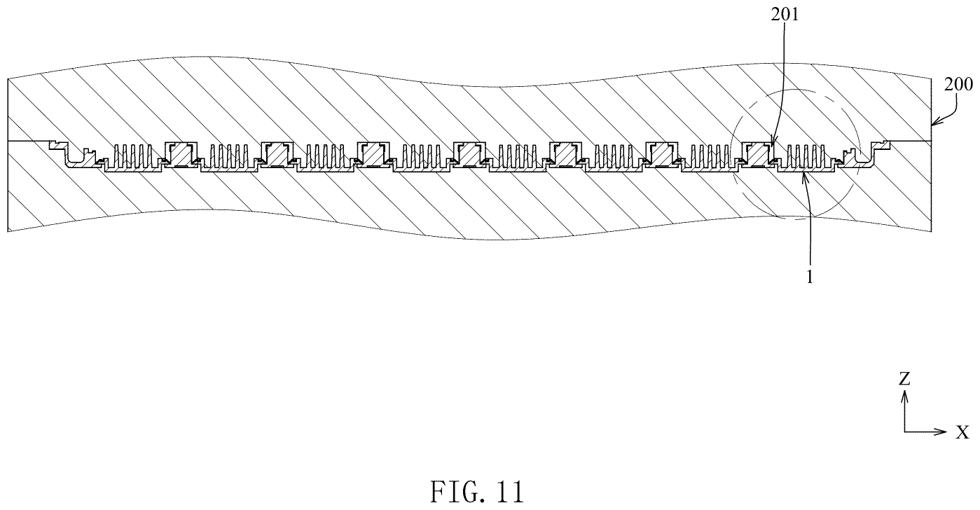

Referring to FIG. 9, FIG. 9 illustrates a manufacturing process of the present embodiment performed by a mold 200 as shown in FIG. 11. The mold 200 defines a mold interior space 201. A manufacturing method of the present embodiment will be described in detail below in combination with FIG. 4 and FIG. 10 to FIG. 14.

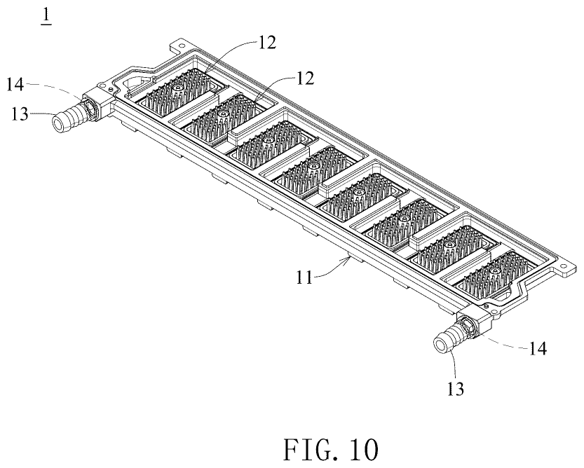

In combination with referring to FIG. 4 and FIG. 10, firstly a step S01 is performed: as shown in FIG. 4, the two sealing rings 14 are firstly coated with an adhesive and then respectively sheathe two joining ends 131 of the main body 11; next, the joining ends 131 of the two joints 13 together with the two sealing rings 14 respectively insert into the two joining holes 113, so that the two joints 13 are respectively communicated with two opposite ends of the passageway space 111, and each sealing ring 14 is adhered to the corresponding joining end 131 and the hole wall of the joining hole 113 with sealing; at the same time, the plurality of heat dissipating seats 12 are respectively placed to the plurality of communication openings 112 via the mount opening 114 with the annular edge portion 124 of each heat dissipating seat 12 abutting against the bottom wall 115, so assembling of the heat dissipating base 1 is completed (see FIG. 10). Here, the main body 11 and the plurality of heat dissipating seats 12 may be formed by cutting a metal material with CNC (computer numerical control) cutting technique or by metal powder Injection Molding (Metal Injection Molding, MIM).

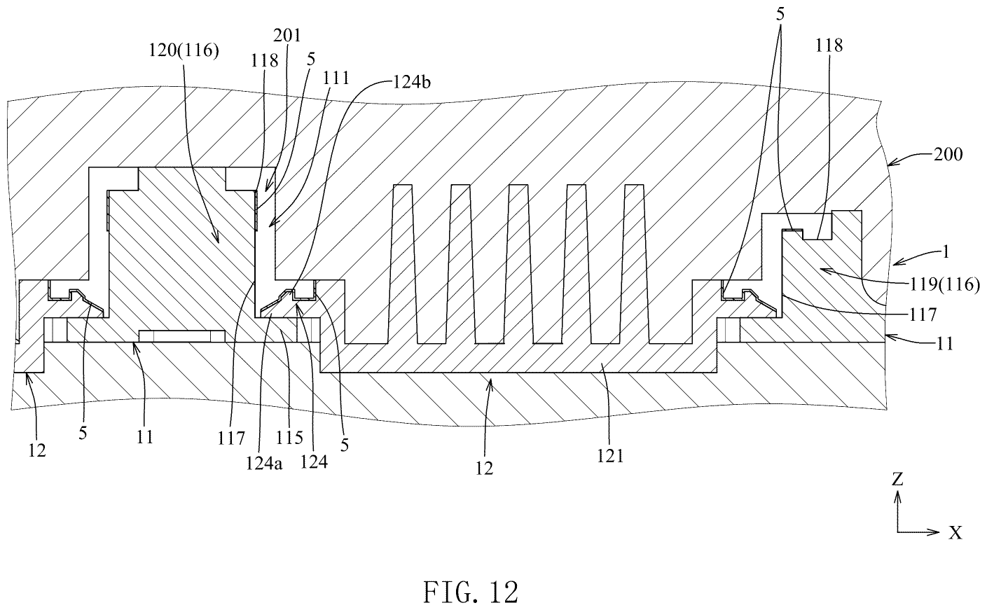

In combination with referring to FIG. 11 and FIG. 12, next a step S02 is performed: the heat dissipating base 1 is placed in the mold 200 (that is, in the mold interior space 201), and the plurality of adhesion promoting layers 5 are respectively provided at the inner surface of the main body 11 away from the heat dissipating seat 12 (that is, the second surface portions 118) and parts of the surfaces of the plurality of heat dissipating seats 12 (that is, one sides of the annular edge portions 124 away from the bottom walls 115), the passageway space 111 is communicated with the mold interior space 201, and a part of the inner surface of the main body 11 adjacent to the heat dissipating seat 12 (that is, the first surface portion 117) is exposed in the mold interior space 201. Here, a manner that the plurality of adhesion promoting layers 5 are provided at the inner surface of the main body 11 and the parts of the surfaces of the plurality of heat dissipating seats 12 may be that a surface treating agent (primer) is sprayed onto the inner surface of the main body 11 and of surfaces of the plurality of annular edge portions 124 (including the top surfaces of the transverse portions 124a and the top surfaces of the protruding edge portions 124b) to form the plurality of adhesion promoting layers 5, and thus the second surface portion 118 of the main body 11 whose material is metal and the parts of the surfaces of the plurality of heat dissipating seats 12 whose material is metal are modified from a characteristic that a surface is not easily adhered to a characteristic that the surface is easily engaged with the molding material 2′.

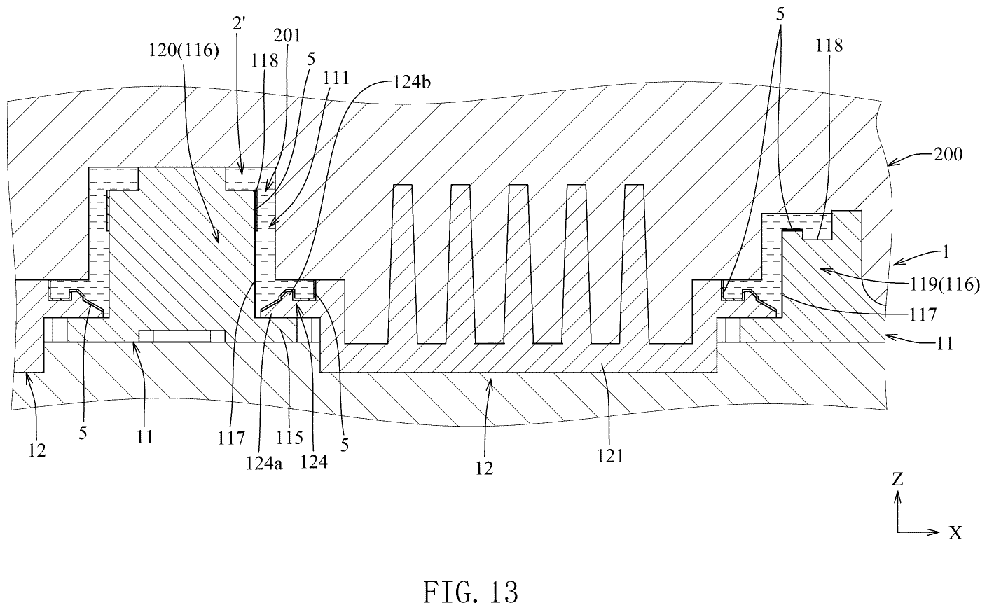

In combination with referring to FIG. 13, next a step S03 is performed: the molding material 2′ is injected into the mold interior space 201 of the mold 200, so that the molding material 2′ is respectively engaged with the main body 11 and the plurality of heat dissipating seats 12 via the plurality of adhesion promoting layers 5, the sealing member 2 (see FIG. 7) which connects the main body 11 and the plurality of heat dissipating seats 12 is formed, and a part of the main body 11 which is not provided with the adhesion promoting layer 5 is separated from the sealing member 2. The floating portion 22 (see FIG. 7) will be separated from the first surface portion 117 of the main body 11 due to the surface material characteristic of the main body 11. Moreover, the molding material 2′ is Liquid Silicone Rubber, which can allow that the floating portion 22 which is not connected with the main body 11 may freely move and generate an elastic force, and further can allow that the sealing member 2 may bear a water pressure of not more than 100 pounds per square inch (100 psi).

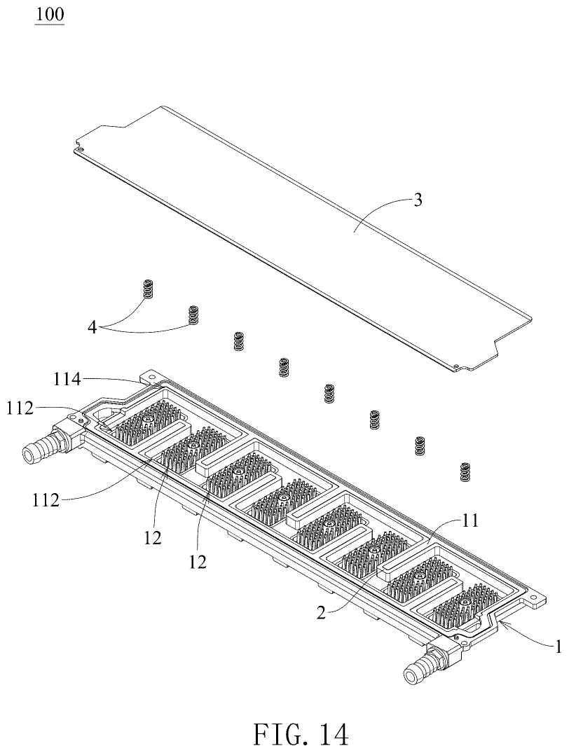

In combination with referring to FIG. 14, next a step S04 is performed: firstly the heat dissipating base 1 together with the sealing member 2 is taken out from the mold 200 as shown in FIG. 13; next, the plurality of elastic members 4 are respectively mounted to one sides of the plurality of heat dissipating seats 12 adjacent to the mount opening 114; then, the outer cover 3 covers a side of the main body 11 away from the plurality of communication openings 112 to close the mount opening 114, so that two opposite ends of each elastic member 4 respectively abut against the outer cover 3 and the corresponding heat dissipating seat 12, so manufacturing of the heat sink assembly 100 is completed. Here, a process that the outer cover 3 covers a side of the main body 11 away from the communication opening 112 to close the mount opening 114 is that the outer cover 3 is engaged with the main body 11 by a welding manner and covers the main body 11, so as to promote sealing between the heat dissipating base 1 and the outer cover 3. Moreover, the outer cover 3 may be formed by cutting a metal material with CNC cutting technique or by a metal powder Injection Molding.

In conclusion, by the design that the floating portion 22 is separated from the main body 11, it can allow the heat dissipating seat 12 to cooperate with contacting and abutting of the pluggable assembly to move relative to the main body 11, avoid the heat dissipating seat 12 generating interference with the pluggable assembly, in turn attain an effect of promoting mounting firmness. On the other hand, by that the inner surface of the main body 11 is provided with the adhesion promoting layer 5, it can allow the sealing member 2 to be connected with the main body 11 via the adhesion promoting layer 5 while the molding material 2′ is cured for formation, and a part of the main body 11 which is not provided with the adhesion promoting layer 5 is separated from the sealing member 2, so as to complete manufacturing of the heat sink assembly 100, so the object of the present disclosure can be indeed attained.

However, the above description is only for the embodiment of the present disclosure, and it is not intended to limit the implementing scope of the present disclosure, and the simple equivalent changes and modifications made according to the claims and the contents of the specification are still included in the scope of the present disclosure.

1. A heat sink assembly, comprising:
a heat dissipating base comprising a main body and at least one heat dissipating seat, an inner surface of the main body defining a passageway space which is adapted to allow a cooling liquid to flow therethrough, the heat dissipating seat being placed in the passageway space; and
a sealing member provided in the passageway space, the sealing member having a fixing portion which is connected to the inner surface of the main body, and a floating portion which is connected to the fixing portion and the heat dissipating seat, the floating portion being separated from the inner surface of the main body and being capable of moving together with the heat dissipating seat relative to the main body.

2. The heat sink assembly of claim 1, wherein
the heat sink assembly further comprises an adhesion promoting layer, a material of the main body is metal, the adhesion promoting layer is provided to the inner surface of the main body and is away from the heat dissipating seat, the fixing portion is connected to the inner surface of the main body via the adhesion promoting layer.

3. The heat sink assembly of claim 2, wherein
the heat sink assembly further comprises another adhesion promoting layer, a material of the heat dissipating seat is metal, the another adhesion promoting layer is provided to a part of a surface of the heat dissipating seat, the floating portion is connected to the heat dissipating seat via the another adhesion promoting layer.

4. The heat sink assembly of claim 2, wherein
a material of the sealing member is Liquid Silicone Rubber which is capable of being cured for formation.

5. The heat sink assembly of claim 1, wherein
the main body further has at least one communication opening which is formed to an outer surface of the main body and is communicated to the passageway space;
the heat dissipating seat has an abutting portion which protrudes from the communication opening, when an inward force is applied to the abutting portion, the floating portion will be brought by the heat dissipating seat to move and be deformed and move toward a direction away from the inner surface of the main body, so as to make the abutting portion withdraw toward an interior of the passageway space.

6. The heat sink assembly of claim 5, wherein
the heat sink assembly further comprises an outer cover and at least one elastic member,
the passageway space has a mount opening which is opposite to the communication opening;
the outer cover covers a side of the main body away from the communication opening to close the mount opening;
two opposite ends of the elastic member respectively abut against the outer cover and the heat dissipating seat;
when the abutting portion withdraws toward the interior of the passageway space, the elastic member will be brought by the heat dissipating seat to move and be compressed and generate an elastic restoring force;
when the inward force applied to the abutting portion is released, the elastic member will be brought by the elastic restoring force to move and restore a length thereof and push the abutting portion out of the passageway space via the communication opening.

7. The heat sink assembly of claim 6, wherein
the elastic member is a spring;
the heat dissipating seat further has an erecting post which extends from the abutting portion toward the outer cover, the erecting post allows the elastic member to sheathe with elastic compressibility.

8. The heat sink assembly of claim 7, wherein
the heat dissipating seat further has an annular encircling wall which encircles the erecting post;
the elastic member is provided between the annular encircling wall and the erecting post, and sheathes the erecting post with elastic compressibility.

9. The heat sink assembly of claim 6, wherein
the main body extends along a length direction, the communication opening and the mount opening are respectively formed to two sides of the main body which are spaced apart from each other in a thickness direction, the thickness direction is not parallel to the length direction,
the heat dissipating base further comprises two joints, the two joints are respectively provided to two sides of the main body which are side by side in the length direction, one of the two joints is used to guide a cooling liquid into the passageway space, the other of the two joints is used to guide the cooling liquid out of the passageway space.

10. The heat sink assembly of claim 9, wherein
the outer surface of the main body at the two sides of the main body which are side by side in the length direction respectively form two joining holes which are communicated to the passageway space, each joint has a joining end, the two joining ends respectively insert into the two joining holes;
the heat dissipating base further comprises two sealing rings which respectively sheathe two joining ends, each sealing ring is used to seal a gap between the corresponding joining end and a hole wall of the joining hole.

11. The heat sink assembly of claim 5, wherein
the main body has a bottom wall which extends along a length direction and a width direction, and an upright wall which extends from the bottom wall along a thickness direction, an inner surface of the bottom wall and an inner surface of the upright wall define the passageway space, the inner surface and an outer surface of the bottom wall are penetrated to form the communication opening, the length direction, the width direction and the thickness direction are not parallel each other;
the heat dissipating seat further has an annular edge portion which movably abuts against the inner surface of the bottom wall, a side of the annular edge portion away from the bottom wall allows the floating portion to be connected therewith.

12. The heat sink assembly of claim 11, wherein
the upright wall has a first surface portion which is connected to the inner surface of the bottom wall and a second surface portion which is connected to the first surface portion,
the second surface portion allows the fixing portion to be connected therewith,
the second surface portion is away from the communication opening relative to the first surface portion, the first surface portion and the inner surface of the bottom wall are separated from the floating portion.

13. The heat sink assembly of claim 11, wherein
the sealing member has a top transverse segment, a longitudinal segment and a bottom transverse segment, the longitudinal segment connects the top transverse segment and the bottom transverse segment,
the floating portion comprises a lower segment of the longitudinal segment and the bottom transverse segment,
the bottom transverse segment extends toward a direction away from the longitudinal segment to connect the annular edge portion of the heat dissipating seat.

14. The heat sink assembly of claim 13, wherein
the annular edge portion of the heat dissipating seat has a transverse portion which extends transversely from a periphery of the abutting portion toward a direction away from the abutting portion and a protruding edge portion which is formed to protrude upwardly from a top surface of the transverse portion,
the protruding edge portion of the heat dissipating seat is positioned between the abutting portion and the longitudinal segment of the sealing member to make the protruding edge portion offset from the longitudinal segment by a distance.

15. The heat sink assembly of claim 1, adapted to be provided to a connector assembly, the connector assembly allowing a pluggable assembly to insert therein, the heat dissipating seat allowing the pluggable assembly to contact and abut thereagainst.

16. A manufacturing method of a heat sink assembly, adapted to be performed by a mold and a heat dissipating base, the heat dissipating base comprising a main body and at least one heat dissipating seat, the manufacturing method of the heat sink assembly comprising:
placing the heat dissipating base into the mold;
providing an adhesion promoting layer on an inner surface of the main body away from the heat dissipating seat;
injecting a molding material into the mold to make the molding material engaged with the main body via the adhesion promoting layer, form a sealing member which connects the main body and the heat dissipating seat, and make a part of the main body which is not provided with the adhesion promoting layer separated from the sealing member; and
taking the heat dissipating base together with the sealing member out of the mold to complete manufacturing of the heat sink assembly.

17. The manufacturing method of the heat sink assembly of claim 16, wherein
the inner surface of the main body defines a passageway space which is adapted to allow a cooling liquid to flow therethrough, and the main body has at least one communication opening which is formed to an outer surface of the main body and is communicated to the passageway space, the passageway space has a mount opening which is opposite to the communication opening, the heat dissipating seat is placed in the passageway space and has an abutting portion which protrudes from the communication opening,
the manufacturing method of the heat sink assembly further comprises:
after taking the heat dissipating base together with the sealing member out the mold, next, mounting at least one elastic member to a side of the heat dissipating seat adjacent to the mount opening,
next, making an outer cover cover a side of the main body away from the communication opening to close the mount opening and make two opposite ends of the elastic member respectively abut against the outer cover and the heat dissipating seat.

18. (canceled)

19. The manufacturing method of the heat sink assembly of claim 17, wherein
the main body extends along a length direction, the communication opening and the mount opening are respectively formed to two sides of the main body which are spaced apart from each other in a thickness direction, the thickness direction is not parallel to the length direction,
the manufacturing method of the heat sink assembly further comprises:
before placing the heat dissipating base into the mold, firstly mounting two joints respectively to two sides of the main body which are side by side in the length direction, so as to make the two joints respectively communicated with two opposite ends of the passageway space.

20. The manufacturing method of the heat sink assembly of claim 19, wherein
the outer surface of the main body at the two sides which are side by side in the length direction respectively form two joining holes which are communicated to the passageway space, each joint has a joining end,
the manufacturing method of the heat sink assembly further comprises:
before mounting the two joints respectively to the two sides of the main body which are side by side in the length direction, firstly coating two sealing rings with an adhesive and then respectively making the two sealing rings sheathe the two joining ends, next, inserting the joining ends of the two joints together with the two sealing rings respectively into the two joining holes, so as to make each sealing ring adhere the corresponding joining end and a hole wall of the joining hole with sealing.

21. (canceled)

22. The manufacturing method of the heat sink assembly of claim 20, wherein
a material of the heat dissipating seat is metal,
the manufacturing method of the heat sink assembly further comprises:
after placing the heat dissipating base into the mold, further providing another adhesion promoting layer on a part of a surface of the heat dissipating seat;
after providing the two adhesion promoting layers respectively on the inner surface of the main body away from the heat dissipating seat and the part of the surface of the heat dissipating seat, injecting a molding material into the mold to make the molding material respectively engaged with the main body and the heat dissipating seat via the two adhesion promoting layers respectively, form the sealing member which connects the main body and the heat dissipating seat, and make the part of the main body which is not provided with the adhesion promoting layer separated from the sealing member.
